(19) United States
(12) Patent Application Publication
(10) Pub. No.: US 2017/0207250 A1
(43) Pub. Date: Jul. 20, 2017

(54) Thin Film Transistor Substrate and Display Device Thereof

(71) Applicant: Wuhan China Star Optoelectronics Technology Co., Ltd., Wuhan (CN)

(72) Inventor: Shangcao Cao, Shenzhen (CN)

(73) Assignee: Wuhan China Star Optoelectronics Technology Co., Ltd., Wuhan, (CN)

(21) Appl. No.: 14/997,737

(22) Filed: Jan. 18, 2016

(51) Int. Cl. H01L 27/12

(52) U.S. Cl. CPC H01L 27/1255

(57) ABSTRACT

The present disclosure discloses a thin film transistor substrate and a display device thereof, which relates to the display technical field. The thin film transistor substrate includes a substrate and a thin film transistor circuit on said substrate, said thin film transistor circuit including an input electrode layer, an output electrode layer and a control electrode layer, said control electrode layer and said output electrode layer composing a first boosting capacitor, when said control electrode layer providing conduction voltage, between said input electrode layer an said output electrode layer electrically conducting. Through the above way, the present disclosure is able to reduce the space of the display panel occupied by the driver circuit.

### BACKGROUND OF THE DISCLOSURE

1. Field of the Disclosure

The present disclosure relates to a display technical field, and in particular to a thin film transistor substrate and a display device thereof.

2. The Related Arts

A TFT, thin film transistor, display device has high response, high contrast and other characteristics, the display effect is close to the traditional CRT, cathode ray tube, display device, in the day of light development of equipment, which has already become the mainstream display device.

The thin film transistor display device includes a display panel, and the display panel includes a display region and a non-display region, wherein each pixel in the display region is driven by the thin film transistor integrated in the back of the pixel, and to achieve a driving connection of a signal-stage pixel through a single scan line, moreover, the driver of the plurality of scan lines corresponded by the plurality of pixels is accomplished by a single made IC, integrated circuit, which is disposed on the display panel around the display region, to control progressive charge and discharge of the scan lines at all levels through the integrated circuit. However, this structure will require to produce a special integrated circuit region on the display panel while producing the display panel, it does not help to reduce the area of the display panel, affecting the development of narrow border display device.

Along with industrial development, people proposed a GOA, gate driver on array, technology, which means to use the original process of the display panel, to use the process similar to the thin film transistor at the back of the pixel to produce the driver circuit of the scan line on the substrate in the non-display region, to make which form one with the substrate in the display region, to alternate the integrated circuit region which is required to adopt another process to produce except the display panel process. The benefit of the gate driver on array technology is to reduce the welding process of the integrated circuit, to improve the productivity and to lower the production costs, moreover, to make the display panel is more suitable for the display device of the narrow border or nor border.

However, the size of the present gate driver on array technology is larger to ensure that the outline integrated circuit is able to output correct voltage, which is still conducive to display panel to develop narrow border or no border.

### SUMMARY OF THE DISCLOSURE

The technical issue to be mainly solved by the present disclosure is to provide a thin film transistor substrate and a display device thereof, which can reduce the space on the display panel occupied by the driver circuit.

In order to solve the above technical issue, a technical solution adopted by the present disclosure is: to provide a thin film transistor substrate.

Wherein, it includes a substrate and a thin film transistor circuit on said substrate, said thin film transistor circuit including an input electrode layer, an output electrode layer and a control electrode layer, said control electrode layer and said output electrode layer composing a first boosting capacitor, when said control electrode layer providing conduction voltage, between said input electrode layer an said output electrode layer electrically conducting.

Wherein, the projections of said output electrode layer and said control electrode layer on said substrate at least partially overlapping.

Wherein, the transistor of said first thin film transistor circuit being N-type MOS transistor, said input electrode being drain layer, said output electrode being source layer, said control electrode layer being gate layer, an active layer being provided between said drain layer and said source layer, said gate layer and said source layer composing said first boosting capacitor, when said gate layer providing conduction voltage, said source layer conducting with said drain layer through said active layer.

Wherein, said active layer and said gate layer composing a second capacitor, said second capacitor being parallel with said first capacitor.

Wherein, said thin film transistor substrate including a second thin film transistor circuit in display region, said first thin film transistor circuit locating in non-display region which is beyond said display region, and said output electrode layer of said first thin film transistor circuit being connected with said second thin film transistor circuit, providing a scan signal to said second thin film transistor circuit.

In order to solve the above technical issue, the other technical solution adopted by the present disclosure is: to provide a display device.

Wherein, it includes a thin film transistor substrate, said thin film transistor substrate includes a substrate and a thin film transistor circuit on said substrate, said thin film transistor circuit including an input electrode layer, an output electrode layer and a control electrode layer, said control electrode layer and said output electrode layer composing a first boosting capacitor, when said control electrode layer providing conduction voltage, between said input electrode layer an said output electrode layer electrically conducting.

Wherein, the projections of said output electrode layer and said control electrode layer on said substrate at least partially overlapping.

Wherein, the transistor of said first thin film transistor circuit being N-type MOS transistor, said input electrode being drain layer, said output electrode being source layer, said control electrode layer being gate layer, an active layer being provided between said drain layer and said source layer, said gate layer and said source layer composing said first boosting capacitor, when said gate layer providing conduction voltage, said source layer conducting with said drain layer through said active layer.

Wherein, said active layer and said gate layer composing a second capacitor, said second capacitor being parallel with said first capacitor.

Wherein, said thin film transistor substrate including a second thin film transistor circuit in display region, said first thin film transistor circuit locating in non-display region which is beyond said display region, and said output electrode layer of said first thin film transistor circuit being connected with said second thin film transistor circuit, providing a scan signal to said second thin film transistor circuit.

The benefit effect of the present disclosure is: to distinguish the situation of the prior art, a first thin film transistor of the present disclosure includes a substrate and a first thin film transistor circuit, the first thin film transistor circuit includes an input electrode layer, an output electrode and a control electrode layer, to make the control electrode layer and the output electrode layer compose a first capacitor, to be able to boost the input voltage of the control electrode layer, to make the thin film transistor circuit easily conduct in the situation of no additional traditional capacitor, to output the correct voltage, thereby helping to reduce the space on the display panel occupied by the driver circuit; at the mean time, when the control electrode layer provides conductive voltage, it also ensures the conduction between the input electrode layer and the output electrode layer.

### BRIEF DESCRIPTION OF THE DRAWINGS

FIG. 1 is a part of a cross-sectional schematic diagram of an embodiment of a thin film transistor substrate of the present disclosure;

FIG. 2 is an equivalent circuit schematic diagram of a thin film transistor circuit in FIG. 1;

FIG. 3 is a specific structure schematic diagram of a thin film transistor substrate in FIG. 2;

FIG. 4 is a top view schematic diagram of an embodiment of a thin film transistor substrate of the present disclosure;

FIG. 5 is a structure schematic diagram of a P-sight thin film transistor substrate;

FIG. 6 is a circuit schematic diagram of a thin film transistor circuit used in scan driver circuit in FIG. 2;

FIG. 7 is another equivalent circuit schematic diagram of a thin film transistor of an embodiment of a thin film transistor substrate of the present disclosure;

FIG. 8 is a equivalent circuit schematic diagram of a thin film transistor of another embodiment of a thin film transistor substrate of the present disclosure;

FIG. 9 is a top view schematic diagram of an embodiment of a display device of the present disclosure.

### DETAILED DESCRIPTION OF THE PREFERRED EMBODIMENTS

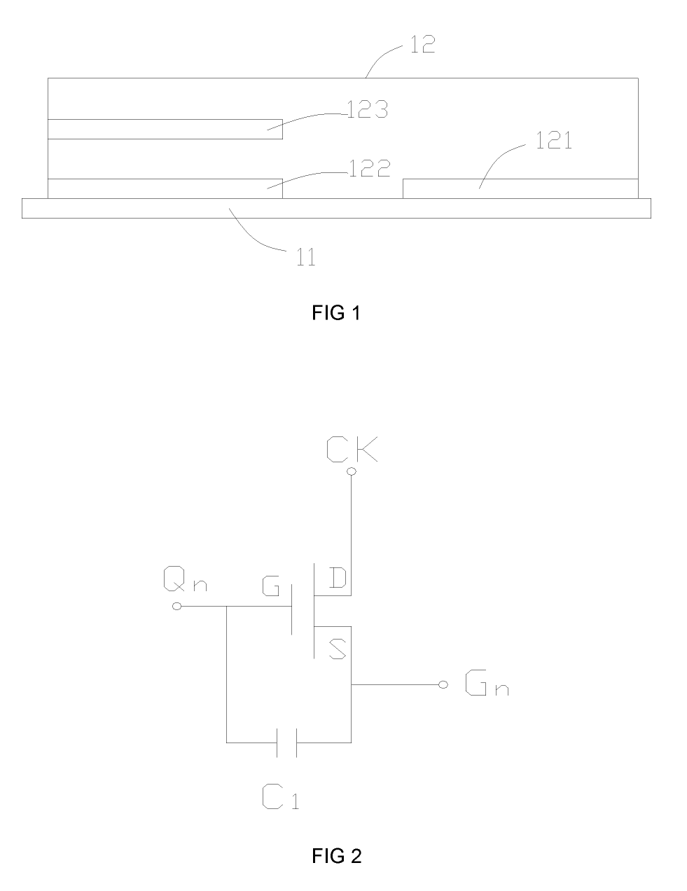

Refer to FIG. 1 and FIG. 2, an embodiment of a thin film transistor substrate of the present disclosure includes: a substrate 11 and a first thin film transistor circuit 12 on the substrate 11, the first thin film transistor circuit 12 includes an input electrode layer 121, an output electrode layer 122 and a control electrode layer 123, the control electrode 123 and the output electrode layer 122 compose a first boosting capacitor C1, when the control electrode layer 123 provides a conduction voltage, between the input electrode layer 121 and the output electrode layer 122 electrically conducts. Wherein the relationship of the electrode layer structure in FIG. 1 and the circuit in FIG. 2 is: the output electrode 121 being D pole, the input electrode 122 being S pole, the control electrode 123 begin G pole.

In the process of the thin film transistor substrate, the control electrode layer 123 and the output electrode layer 122 are made of a bipolar plate to form a first capacitor C1, eliminating the need for an additional capacitor of the traditional GOA technology, in order to ensure the electrical conduction between the input electrode layer 121 and the output electrode layer 122 when the control electrode layer provides the conduction voltage, thereby reducing the space on the display panel occupied by the driver circuit, meeting the requirements of narrow border, light and thin of the display panel.

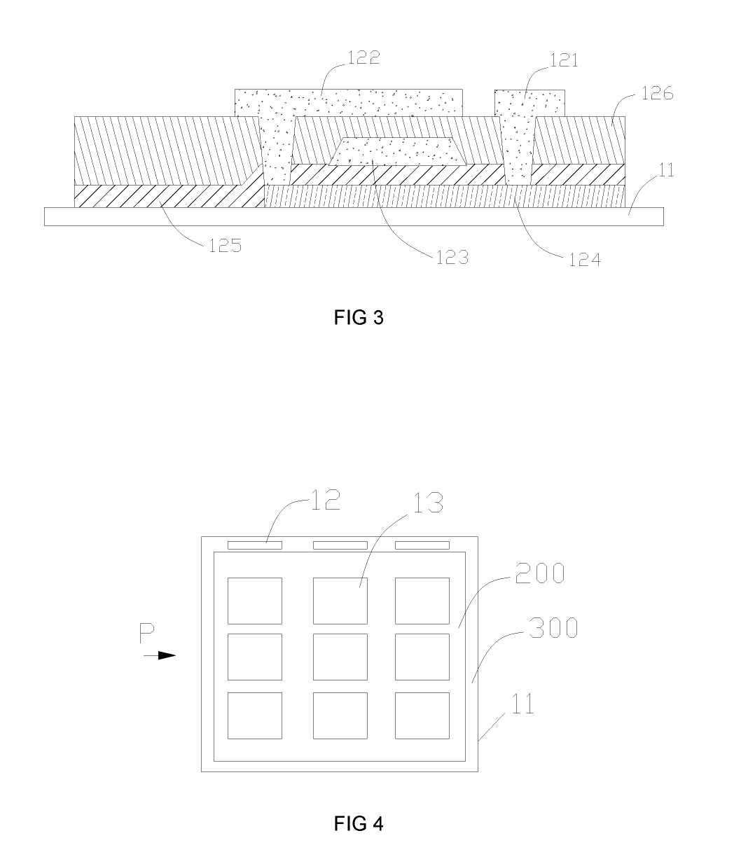

Refer to FIG. 1 and FIG. 3, the projections of the output electrode layer 122 and the control electrode layer 123 on the substrate 11 at least partially overlap, the output electrode 122 and the control electrode layer 123 are conductor, to compose a first capacitor C1.

Refer to FIG. 1, FIG. 2 and FIG. 3, the transistor of the thin film transistor circuit 12 of the present embodiment is N-type MOS transistor, and the input electrode layer 121 of which is drain layer, the output electrode 122 is source layer, the control electrode layer 123 is gate layer, there is an active layer 124 disposed between the drain layer and the source layer, the gate layer and the source layer compose a first boost capacitor C1, when the gate layer provides the conduction voltage, the source layer and the drain layer electrically conduct through the active layer 124. The gate layer and the source layer compose the first boost capacitor C1, which is equivalent to the traditional capacitor that occupied an additional space of the display panel of the traditional GOA technology, effectively improving the space utilization of the thin film transistor substrate, solving the problem that traditional capacitor requires to occupy the space of the display panel.

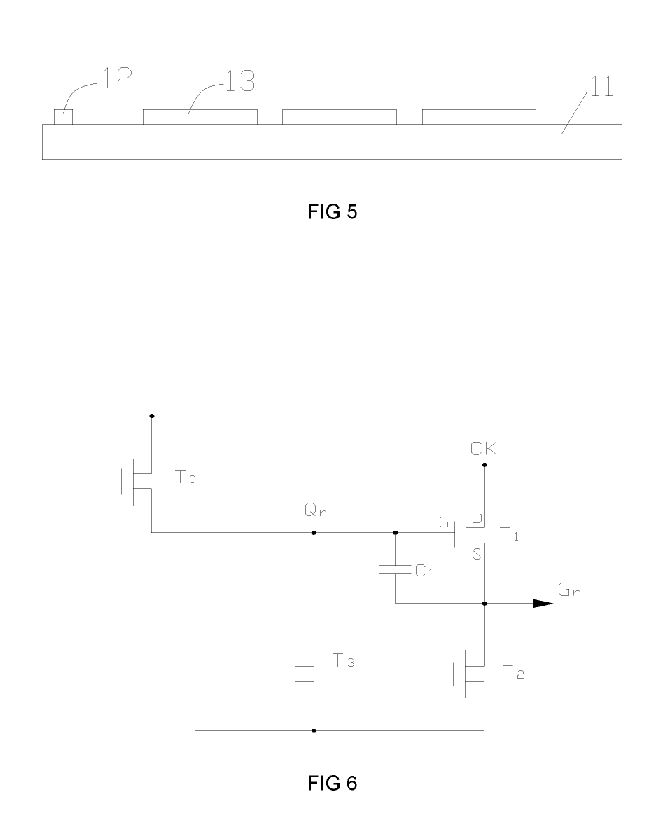

Refer to FIG. 4, FIG. 5 and FIG. 6, in the present embodiment, the thin film transistor substrate includes a second thin film transistor circuit 13 in the display region 200, a thin film transistor circuit 12 is the non-display region 300 beyond the display region, and the output electrode layer 122 of the thin film transistor circuit 12 is connected with the second thin film transistor circuit 13, to provide the scan signal to the second thin film transistor circuit 13, in the premise of ensuring the electrical conduction between the input electrode layer 121 and the output electrode layer 122, to provide a more stable scan signal for the second thin film transistor circuit 12, improving the display stability of the display region 200.

Refer to FIG. 6, the embodiment of the first thin film transistor circuit of the present disclosure could be used in the scan driver circuit, the scan driver circuit includes a downstream module T0, an output module T1 and drop-down modules T2, T3, Qn is control end, CK is input end, Gn is output end, wherein the output module T1 determine the output voltage of the gate, the output module T1 includes a thin film transistor of the present disclosure, to ensure the output quality of the scan line.

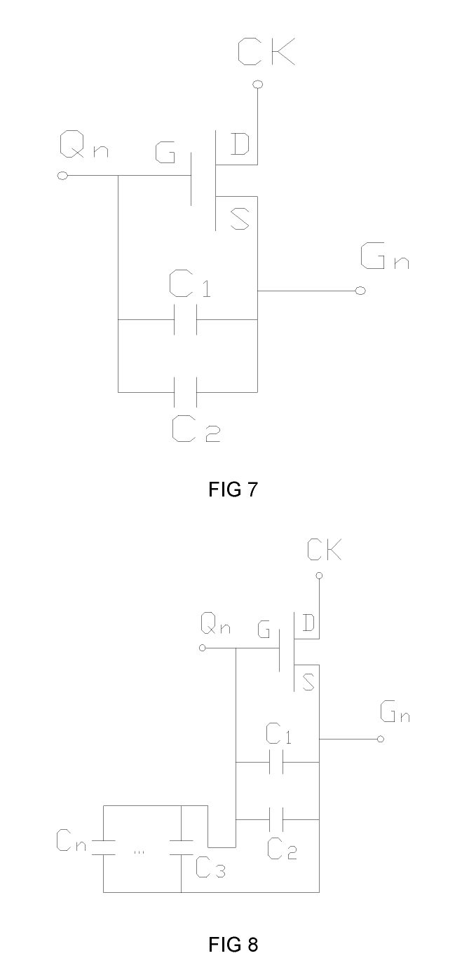

Refer to FIG. 7, the other embodiment of the thin film transistor substrate is base on the above embodiment, furthermore, the gate electrode layer and the source layer compose a second capacitor C2, the second capacitor C2 is parallel with the first capacitor C1, to improve the capacitance, better ensuring the electrical conduction of thin film transistors.

Refer to FIG. 2 and FIG. 8, for requirement of external capacitor of the display panel, it cloud be based on the above embodiment, to add any capacitor C3 . . . Cn according to the actual requirement, to meet the needs of practical applications, and it has a certain flexibility.

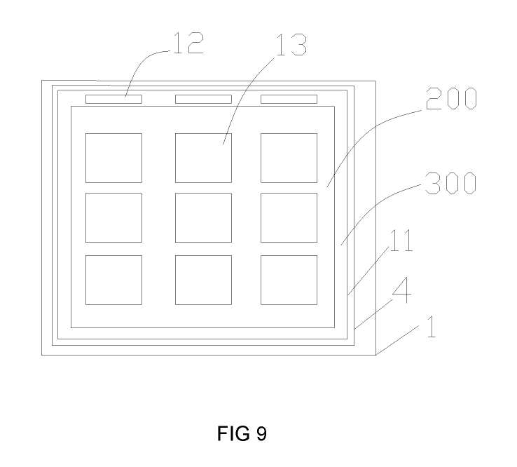

Refer to FIG. 1, FIG. 2, FIG. 4 and FIG. 9, the present disclosure also provides a display device 1, which includes a substrate 11 of the thin film transistor substrate of the above embodiment and another stacked substrate 4. The control electrode layer 123 and the output electrode 122 compose a first capacitor C1, to solve the problem that traditional capacitor requires to occupy the space of the display panel, meeting the requirements of narrow border, light and thin of the display panel. At the mean time, in the premise of ensuring the electrical conduction between the input electrode layer 121 and the output electrode layer 122, to provide a more stable scan signal for the second thin film transistor circuit 12, thereby improve the display stability of the display device 1.

The preferred embodiments according to the present disclosure are mentioned above, which cannot be used to define the scope of the right of the present disclosure. Those variations of equivalent structure or equivalent process according to the present specification and the drawings or directly or indirectly applied in other areas of technology are considered encompassed in the scope of protection defined by the clams of the present disclosure.

1. A thin film transistor substrate, the characteristic of which includes: a substrate and a thin film transistor circuit on said substrate, said thin film transistor circuit including an input electrode layer, an output electrode layer and a control electrode layer, said control electrode layer and said output electrode layer composing a first boosting capacitor, when said control electrode layer providing conduction voltage, between said input electrode layer an said output electrode layer electrically conducting. Projections of said output electrode layer and said control electrode layer on said substrate at least partially overlapping, and projections of said input electrode layer and said control electrode layer on said substrate not overlapping.

2. (canceled)

3. The thin film transistor substrate as claimed in claim 1, the characteristic of which is said transistor of said first thin film transistor circuit being N-type MOS transistor, said input electrode being drain layer, said output electrode being source layer, said control electrode layer being gate layer, an active layer being provided between said drain layer and said source layer, said gate layer and said source layer composing said first boosting capacitor, when said gate layer providing conduction voltage, said source layer conducting with said drain layer through said active layer.

4. The thin film transistor substrate as claimed in claim 3, the characteristic of which is said active layer and said gate layer composing a second capacitor, said second capacitor being parallel with said first capacitor.

5. The thin film transistor substrate as claimed in claim 1, the characteristic of which is said thin film transistor substrate including a second thin film transistor circuit in display region, said first thin film transistor circuit locating in non-display region which is beyond said display region, and said output electrode layer of said first thin film transistor circuit being connected with said second thin film transistor circuit, providing a scan signal to said second thin film transistor circuit.

6. A display device the characteristic of which includes a thin film transistor substrate, said thin film transistor substrate includes a substrate and a thin film transistor circuit on said substrate, said thin film transistor circuit including an input electrode layer, an output electrode layer and a control electrode layer, said control electrode layer and said output electrode layer composing a first boosting capacitor, when said control electrode layer providing conduction voltage, between said input electrode layer an said output electrode layer electrically conducting. Projections of said output electrode layer and said control electrode layer on said substrate at least partially overlapping, and projections of said input electrode layer and said control electrode layer on said substrate not overlapping.

7. (canceled)

8. The display device as claimed in claim 6, the characteristic of which is said transistor of said first thin film transistor circuit being N-type MOS transistor, said input electrode being drain layer, said output electrode being source layer, said control electrode layer being gate layer, an active layer being provided between said drain layer and said source layer, said gate layer and said source layer composing said first boosting capacitor, when said gate layer providing conduction voltage, said source layer conducting with said drain layer through said active layer.

9. The display device as claimed in claim 8, the characteristic of which is said active layer and said gate layer composing a second capacitor, said second capacitor being parallel with said first capacitor.

10. The display device as claimed in claim 6, the characteristic of which is said thin film transistor substrate including a second thin film transistor circuit in display region, said first thin film transistor circuit locating in non-display region which is beyond said display region, and said output electrode layer of said first thin film transistor circuit being connected with said second thin film transistor circuit, providing a scan signal to said second thin film transistor circuit.
